(19) United States
(12) Patent Application Publication
(10) Pub. No.: US 2014/0254119 A1
(43) Pub. Date: Sep. 11, 2014

(54) ANISOTROPIC CONDUCTIVE FILM, DISPLAY DEVICE, AND MANUFACTURING METHOD OF DISPLAY DEVICE

(71) Applicant: Samsung Display Co., Ltd., Yongin-City (KR)

(72) Inventor: Dae-Hyuk IM, Yongin-City (KR)

(73) Assignee: Samsung Display Co., Ltd., Yongin-City (KR)

(21) Appl. No.: 14/201,112

(22) Filed: Mar. 7, 2014

(30) Foreign Application Priority Data
Mar. 8, 2013 (KR) 10-2013-0025114

(51) Int. Cl. C09J 9/02; H05K 7/02

(52) U.S. Cl. CPC C09J 9/02; H05K 7/02
USPC 361/767; 361/820; 428/352; 442/1; 156/249

(57) ABSTRACT

An anisotropic conductive film includes an adhesive layer formed of a polymer resin, conductive particles dispersed in the adhesive layer, a support layer disposed at one side of the adhesive layer and maintaining the adhesive layer in a film shape, and a releasing sheet disposed at one side of the support layer.

### CROSS-REFERENCE TO RELATED APPLICATION

The present application claims priority under 35 U.S.C. §119 to Korean Patent Application No. 10-2013-0025114, filed on Mar. 8, 2013, in the Korean Intellectual Property Office, and entitled: “Anisotropic Conductive Film Display Device, and Manufacturing Method of Display Device,” which is incorporated by reference herein in its entirety.

### BACKGROUND

1. Field

Embodiments relate to an anisotropic conductive film, a display device, and a method of manufacturing a display device.

2. Description of the Related Art

An anisotropic conductive film (ACF) may perform electric connection and physical bonding within a short period time with respect to several hundreds of electrodes disposed at a very small distance from each other.

The above information disclosed in this Background section is only for enhancement of understanding of the background of the described technology and therefore it may contain information that does not form the prior art that is already known in this country to a person of ordinary skill in the art.

### SUMMARY

Embodiments are directed to an anisotropic conductive film, including an adhesive layer formed of a polymer resin, conductive particles dispersed in the adhesive layer, a support layer disposed at one side of the adhesive layer and maintaining the adhesive layer in a film shape, and a releasing sheet disposed at one side of the support layer.

The support layer may be formed in the shape of a mesh having a plurality of openings.

A diameter of each of the plurality of openings may be greater than a diameter of the conductive particles.

The openings may have a size that is about 10 to about 20 times greater than a diameter of the conductive particles.

A heat resisting temperature of the support layer may be higher than a thermal curing temperature of the polymer resin.

The support layer may include one or more of polyphenylene sulfide, polyetheretherketone, polyphthalamide, thermoplastic polyimide, polysulfone, polyethersulfone, or polyetherimide.

The support layer may be formed of an insulation layer having a rupture pressure of about 2 MPa to about 3 MPa.

The support layer may be formed of an insulation layer having a melting temperature that is lower than a thermal curing temperature of the polymer resin.

The adhesive layer may include a first layer in which the conductive particles are disposed in the polymer resin, and a second layer formed of only the polymer resin.

Embodiments are also directed to a method of manufacturing a display device, the method including preparing an adhesive layer, conductive particles being dispersed into the adhesive layer, a support layer being disposed at one side of the adhesive layer and maintaining the adhesive layer in a film shape, and a releasing sheet being disposed at one side of the support layer, removing the releasing sheet, disposing the adhesive layer and the support layer on a first pad portion of a display panel, and disposing a second pad portion of a chip on film on the adhesive layer and the support layer, and connecting and bonding the first pad portion and the second pad portion to each other by thermally compressing the support layer.

The support layer may be formed in the shape of a mesh having a plurality of openings, and a heat resisting temperature of the support layer may be higher than a thermal curing temperature of the adhesive layer.

A material of the adhesive layer may fill the plurality of openings during the thermo-compression process, and the conductive particles may be disposed between electrodes of the first pad portion and electrodes of the second pad portion in the plurality of openings.

The support layer may have a rupture pressure of about 2 MPa to about 3 MPa, and the support layer is ruptured during the thermo-compression process such that the material of the adhesive layer and the conductive particles penetrate the support layer.

The support layer may have a melting temperature that is lower than a thermal curing temperature of the adhesive layer, and may be melted and then diffused during the thermo-compressing process.

Embodiments are also directed to a display device, including a display panel provided with a first pad portion, a chip on film provided with a second pad portion that faces the first pad portion, and a first anisotropic conductive film disposed between the first pad portion and the second pad portion, the first anisotropic conductive film connecting and bonding the first pad portion and the second pad portion to each other. The first anisotropic conductive film may include an adhesive layer formed of a polymer resin, conductive particles connecting the first pad portion and the second pad portion, and a support layer disposed at one side of the adhesive layer.

The support layer may be formed in the shape of a mesh forming a plurality of openings filled with the polymer resin.

The support layer may form a plurality of rupture openings, and the polymer resin and the conductive particles may penetrate the support layer in the plurality of rupture openings.

The chip on film may be provided with a third pad portion, the display device may further include a printed circuit board provided with a fourth pad portion facing the third pad portion, and a second anisotropic conductive film disposed between the third pad portion and the fourth pad portion to connect and bond the third pad portion and the fourth pad portion to each other, and the second anisotropic conductive film may include an adhesive layer formed of a polymer resin, conductive particles connecting the third pad portion and the fourth pad portion, and a support layer disposed at one side of the adhesive layer.

The support layer of the second anisotropic conductive film may be formed in the shape of a mesh forming a plurality of openings filled with the polymer resin.

The support layer of the second anisotropic conductive film may form a plurality of rupture openings, and the polymer resin and the conductive particles of the second anisotropic conductive film may penetrate the support layer of the second anisotropic conductive film in the plurality of rupture openings.

### BRIEF DESCRIPTION OF THE DRAWINGS

Features will become apparent to those of skill in the art by describing in detail example embodiments with reference to the attached drawings in which:

FIG. 1 illustrates a cross-sectional view of an anisotropic conductive film according to a first example embodiment.

FIG. 2 illustrates a top plan view of the anisotropic conductive film of FIG. 1.

FIG. 3 is a cross-sectional view of an example variation of the anisotropic conductive film of FIG. 1.

FIG. 4 illustrates a cross-sectional view of an anisotropic conductive film according to a second example embodiment.

FIG. 5 illustrates a cross-sectional view of an anisotropic conductive film according to a third example embodiment.

FIG. 6 illustrates a process flowchart of stages in a manufacturing method of a display device according to the example embodiment.

FIG. 7 and FIG. 8 illustrate top plan views respectively illustrating a display panel and an anisotropic conductive film in the third operation of FIG. 6.

FIG. 9 illustrates a cross-sectional view of the display device in the fourth operation of FIG. 6.

FIG. 10 illustrates a cross-sectional view of another example variation of the fourth operation of FIG. 6.

FIG. 11 illustrates a cross-sectional view of another example variation of the fourth operation of FIG. 6.

FIG. 12 illustrates a partial cross-sectional view of the display device according to the example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

In the specification, unless explicitly described to the contrary, the word “comprise,” and variations such as “comprises” or “comprising,” will be understood to imply the inclusion of stated elements but not the exclusion of any other elements. It will be understood that when an element such as a layer, film, region, or substrate is referred to as being “on” another element, it may be directly on the other element or intervening elements may also be present. Further, in the specification, it will be understood that an upper part of a target portion indicates an upper part or a lower part of a target portion, and it does not mean that the target portion is always positioned at the upper side based on a gravity direction.

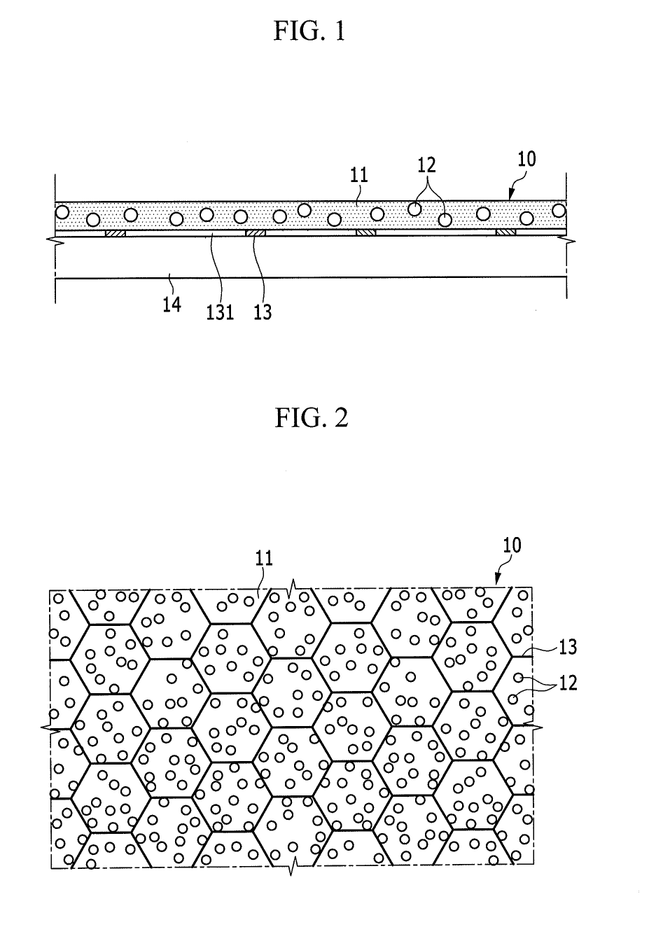

FIG. 1 illustrates a cross-sectional view of an anisotropic conductive film according to a first example embodiment, and FIG. 2 is a top plan view of the anisotropic conductive film of FIG. 1.

Referring to FIG. 1 and FIG. 2, an anisotropic conductive film 10 according to the first example embodiment includes an adhesive layer 11, conductive particles 12, a support layer 13, and a releasing sheet 14. The conductive particles 12 are dispersed into the adhesive layer 11, and support layer 13 maintains the adhesive layer 11 in a film shape. The support layer 13 has a plurality of openings 131. The releasing sheet 14 is disposed at one side of the support layer 13.

The adhesive layer 11 may be formed of an insulating polymer resin that is soft by thermal compression and then cured at a predetermined temperature. For example, the adhesive layer 11 may include one or more of a thermosetting polymer resin, a thermoplastic polymer resin, a radical-polymerized polymer resin, or a rubber-based resin polymer.

Examples of the thermosetting polymer resin include an epoxy resin, a phenol resin, a melamine resin, and the like. Examples of the thermoplastic polymer resin include a styrene butadiene resin, an ethylene vinyl resin, an ester resin, a silicone resin, a phenoxy resin, an acryl resin, an amide-based resin, a vinylbutyral resin, and the like. Examples of the radical-polymerized polymer resin include methylacrylate, ethylacrylate, bisphenol A ethyleneglycol modified diacrylate, and the like. Examples of the rubber-based resin polymer include an acrylonitrile-based polymer resin, a styrene butadiene-based polymer resin, a neoprene-based polymer resin, a styrene acrylonitrile-based polymer resin, a butadiene-based polymer resin, and the like.

In an implementation, the adhesive layer 11 may include an agent such as a filler, a softener, a colorant, a flame retardation agent, a light stabilizer, a cross-linking agent, and the like.

The conductive particles 12 are provided for electric connection, and may be evenly dispersed in the adhesive layer 11. The conductive particles 12 may be formed of, e.g., metal particles or particles of which the cores are made of an insulating material and the surfaces are coated with a metal. The metal may include one or more of, e.g., nickel (Ni), iron (Fe), copper (Cu), aluminum (Al), tin (Sn), zinc (Zn), chromium (Cr), cobalt (Co), gold (Au), silver (Ag), etc.

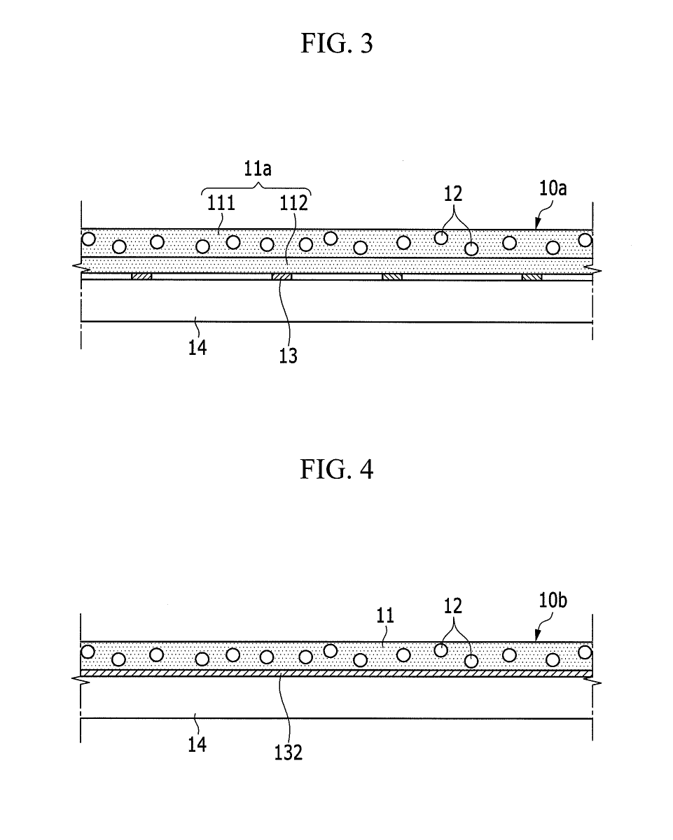

FIG. 3 illustrates a cross-sectional view of an example variation of the anisotropic conductive film shown in FIG. 1.

Referring to FIG. 3, the adhesive layer 11a may be formed of a first layer 111 where the conductive particles 12 are dispersed and a second layer 112 where the conductive particles 12 are not dispersed. In this case, adherence of the anisotropic conductive film 10a may be further reinforced and stable connection may be performed.

Referring back to FIG. 1 and FIG. 2, the support layer 13 may be formed of an insulation layer disposed at one side of the adhesive layer 11 with a predetermined thickness. The support layer 13 may have a plurality of openings 131 formed in the shape of a mesh. Each of the plurality of openings 131 may be formed to be greater in size than the conductive particle 12. For example, the size of each of the openings 131 may be set to be 10 times to 20 times the diameter of the conductive particle 12.

The adhesive layer 11 and the conductive particles 12 dispersed therein may fill the openings 131 of the support layer 13 during a thermo-compression process. Therefore, during a thermo-compression process of the anisotropic conductive film 10 after removing of the releasing sheet 14, the electrode of the display panel and the electrode of the chip on film (COF) may be electrically connected by the conductive particles 12 in the opening 131 and may be physically bonded to each other by a material of the adhesive layer 11 filling the opening 131.

The opening 131 of the support layer 13 may be formed in various shapes such as a circle, a triangle, a quadrangle, or a polygon having more than 5 angles. FIG. 2 exemplarily illustrates the support layer 13 formed in the shape of a mesh having hexagon-shaped openings 131.

An internal heat resisting temperature of the support layer 13 may be higher than a thermal curing temperature of the adhesive layer 11. Therefore, the support layer 13 may not be influenced by the thermo-compression process of the anisotropic conductive film 10, which may help maintain the initial shape thereof.

The support layer 13 may be formed of high heat-resistant resin having heat-resistant temperature of higher than, e.g., about 180° C. In an implementation, the support layer 13 may include one or more of polyphenylene sulfide, polyetheretherketone, polyphthalamide, thermoplastic polyimide, polysulfone, polyethersulfone, or polyetherimide.

The support layer 13 may remain between the display panel and the chip on film. The support layer 13 may be formed of an insulation material and thus it may not influence the electric connection between the display panel and the chip on film. Further, the mesh shape may have a narrow width and may not substantially interfere with the physical bonding between the display panel and the chip on film.

The support layer 13 may have constant tension by having a fine mesh structure. Thus, after the releasing sheet 14 is removed, the adhesive layer 11 may maintain the film shape by the support layer 13, thereby facilitating handling. By contrast, a typical anisotropic conductive film may not maintain a film shape only by the adhesive layer without having the releasing sheet, and accordingly a pre-compression process is typically performed before the main compression process when using a typical film.

As described above, the anisotropic conductive film 10 of the present example embodiment may maintain the adhesive layer 11 in the film shape without having the releasing sheet 14 so that the handling of the adhesive layer 11 may be facilitated even through the releasing sheet 14 is removed. Therefore, the anisotropic conductive film 10 according to the present example embodiment may connect the display panel and the chip on film through a main compression process without performing a pre-compression process. A process for connecting the display panel and the chip on film using the anisotropic conductive film 10 will be described in detail below.

FIG. 4 illustrates a cross-sectional view of an anisotropic conductive film according to a second example embodiment.

Referring to FIG. 4, an anisotropic conductive film 10b according to the second example embodiment may be the same as the anisotropic conductive film of the first example embodiment, except that a support layer 132 is formed throughout one surface of the adhesive layer 11 and is configured to be ruptured by a pressure applied thereto during thermo-compression. The same reference numerals refer to the same members as the first example embodiment.

In the present example embodiment, the support layer 132 is disposed throughout one surface of the adhesive layer 11 that faces a releasing sheet 14 so that a material of the adhesive layer 11 at a surface where the releasing sheet 14 is removed may be prevented from being exposed. The support layer 132 may maintain constant tension so that the adhesive layer 11 may maintain the film shape after the releasing sheet 14 is removed. Therefore, handling of the adhesive layer 11 after removing of the releasing sheet 14 may be facilitated so that a pre-compression process may be omitted.

In the present example embodiment, the support layer 132 is ruptured due to the pressure applied during the thermo-compression process so that conductive particles 12 and the material of the adhesive layer 11 may penetrate the support layer 132. For example, the support layer 132 may be formed of an insulation layer having a rupture pressure of about 2 MPa to about 3 MPa. Thus, the conductive particles 12 and the material of the adhesive layer 11 may penetrate the support layer 132 as the support layer 132 is ruptured through the thermo-compression process of the anisotropic conductive film 10b after removing the releasing sheet 14. As a result, the electrode of the display panel and the electrode of the chip on film may be electrically connected by the conductive particles 12 that penetrate the support layer 132, and may be physically bonded by the material of the adhesive layer 11 that penetrates the support layer 132.

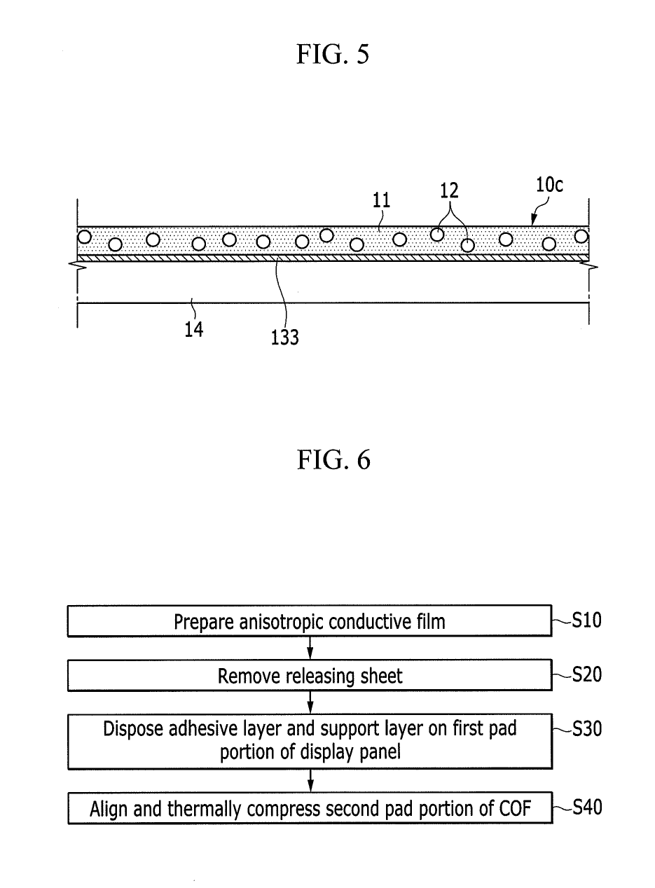

FIG. 5 illustrates a cross-sectional view of an anisotropic conductive film according to a third example embodiment.

Referring to FIG. 5, an anisotropic conductive film 10c according to a third example embodiment may be the same as the anisotropic conductive film of the second example embodiment, except that a support layer 133 is melted by heat applied during a thermo-compression process. The same reference numerals refer to the same members as the second example embodiment.

In the present example embodiment, the support layer 133 may be melted by heat applied during the thermo-compression process and then diffuse. The support layer 133 may be formed of a polymer resin having a melting temperature that is lower than a thermal curing temperature of the film. For example, the support layer 133 may be formed of a low-melting point polymer resin having a melting temperature of lower than about 160° C. to about 180° C., which may be the thermal curing temperature.

In the present example embodiment, the support layer 133 may maintain a constant tension in a room temperature so that the adhesive layer 11 may maintain the film shape after the releasing sheet 14 is removed. Then, the support layer 133 may be melted by heat and then diffuse during the thermo-compression process. Accordingly, the electrode of the display panel and the electrode of the chip on film may be electrically connected by conductive particles 12 may be physically bonded by a material of the adhesive layer 11.

In the anisotropic conductive films 10, 10b, and 10c of the above-stated first to third example embodiments, the support layers 13, 132, and 133 are commonly disposed at one side of the adhesive layer 11, and are configured to maintain constant tension without influencing the electric connection and physical bonding of the display panel and the chip on film so that the adhesive layer 11 may maintain the film shape after the releasing sheet 14 is removed.

FIG. 6 illustrates a process flowchart of stages in a manufacturing method of a display device according to an example embodiment.

Referring to FIG. 6, a manufacturing method of a display device according to the present example embodiment includes: a first operation (S10) for preparing an anisotropic conductive film; a second operation (S20) for removing a releasing sheet from the anisotropic conductive film; a third operation (S30) for arranging an adhesive layer and a support layer on a first pad portion of the display panel; and a fourth operation (S40) for thermo-compressing the adhesive layer and the support layer after arranging a second pad portion of a chip on film on the adhesive layer and the support layer to connect and bond the first pad portion and the second pad portion.

In the first operation (S10), the anisotropic conductive includes an adhesive layer, conductive particles, a support layer, and a releasing sheet, and may have a structure of any one of the first to third example embodiments.

In the second operation (S20), the releasing sheet is separated from the support layer. The support layer may maintain a constant tension. The support layer may prevent an adhesive layer material from being exposed through a surface where the releasing sheet is separated. According to embodiments, the adhesive layer may maintain the film shape by the support layer even though the releasing sheet is removed so that a worker or a machine of an automation process may easily move or transport the adhesive layer.

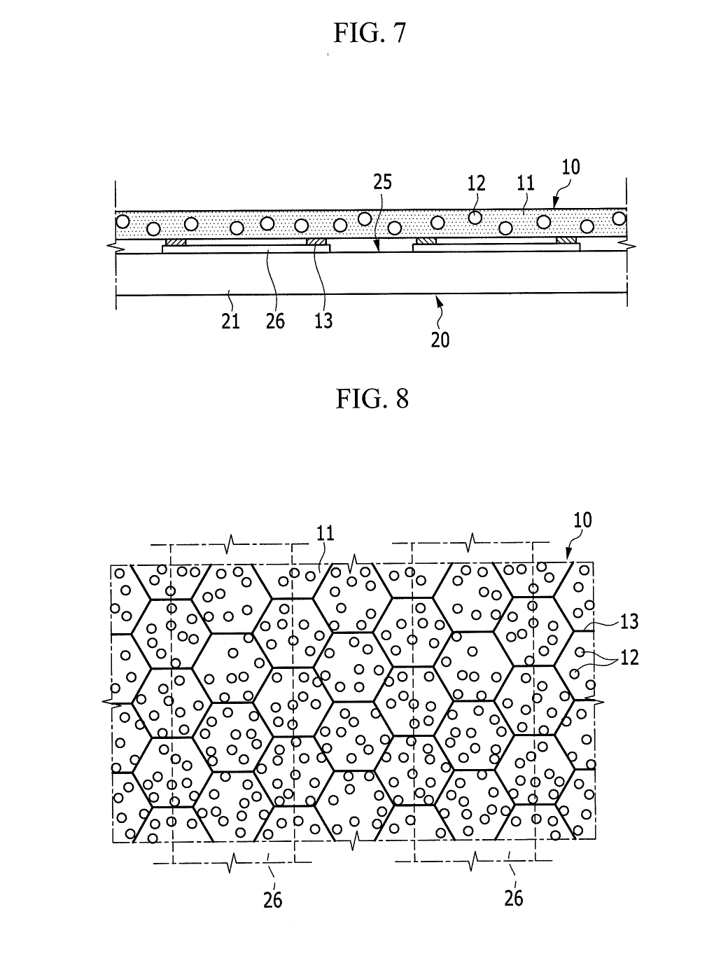

FIG. 7 and FIG. 8 illustrate a cross-sectional view and a top plan view schematically illustrating the display panel and the anisotropic conductive film in the third operation shown in FIG. 6.

Referring to FIG. 7 and FIG. 8, the adhesive layer 11 and the support layer 13 in the third operation (S30) are transported, e.g., by the hand of the worker or the machine of the automation process, and disposed on the first pad portion 25 of the display panel 20. The first pad portion 25 may be formed of a plurality of first pad electrodes 26, which may be disposed at a distance from each other on the first substrate 21.

In FIG. 7 and FIG. 8, the anisotropic conductive film 10 provided with the mesh-shaped support layer 13 according to the first example embodiment is exemplarily illustrated. The mesh-shaped support layer 13 may have a micro width, and therefore the support layer 13 may does not cause deterioration in adherence or electric connection.

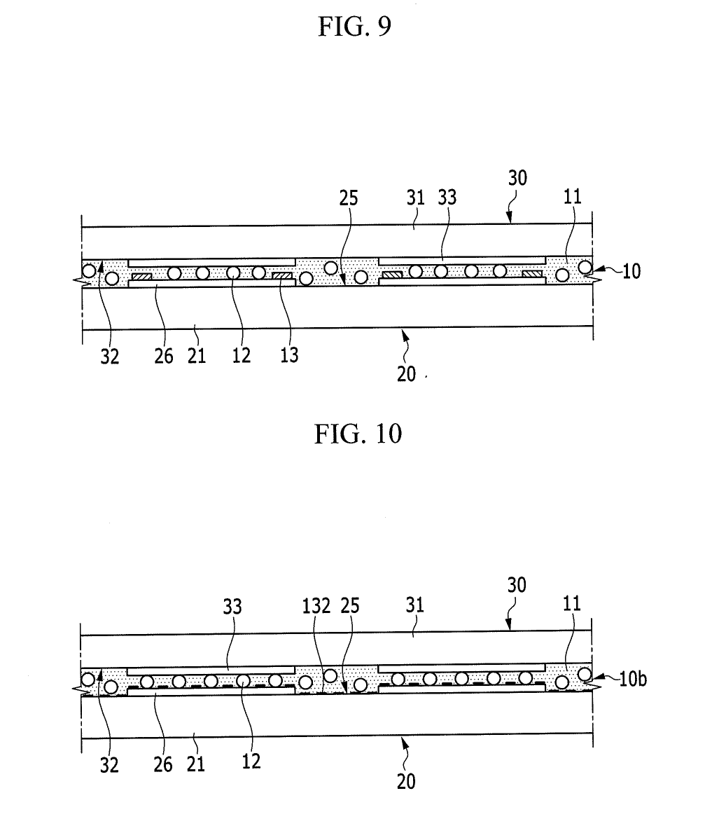

FIG. 9 illustrates a cross-sectional view of the display device of the fourth operation shown in FIG. 6.

Referring to FIG. 9, the second pad portion 32 of the chip on film 30 is disposed on the adhesive layer 11 and the support layer 13 in the fourth operation (S40). The second pad portion 32 may be formed of a plurality of output-side wire electrodes 33, which may be disposed at a distance from each other on a base film 31. The first pad electrode 26 and the output-side wire electrode 33 may have the same pitch and the same width, and the chip on film 30 may be aligned to make the output-side wire electrodes 33 face one to one to the first pad electrodes 25 on the adhesive layer 11 and the support layer 13.

In an implementation, the chip on film 30 may be replaced with, e.g., a tape carrier package (TCP) or a flexible printed circuit (FPC).

Subsequently, heat and pressure may be applied to the first pad portion 25 and the second pad portion 32. The adhesive layer 11 may be softened and pressed by the pressure so than the material of the adhesive layer 11 is filled between the first pad electrodes 26 and between the output-side wire electrodes 33 while filling openings of the support layer 13.

The conductive particles 12 may electrically connect the first pad electrode 26 and the output-side wire electrode 33 while contacting the two electrodes 26 and 33 therebetween. After that, the adhesive layer 11 may be firmly bonded between the first pad portion 25 and the second pad portion 32 while being cured. In such a thermo-compression process, a heat resistance temperature of the support layer 13 may be higher than a thermal curing temperature of the adhesive layer 11, and the support layer 13 may maintain the initial state without being thermally deformed.

FIG. 10 illustrates a cross-sectional view of another example embodiment of the fourth operation shown in FIG. 6.

Referring to FIG. 10, when a display device includes the anisotropic conductive film 10b of the second example embodiment, conductive particles 12 and a material of the adhesive layer 11 may penetrate the support layer 132 while the support layer 132 is ruptured during the thermo-compression process of the fourth operation. The thermo-compression process of the fourth operation may be performed for, e.g., about 10 to about 20 seconds at a temperature of about 160° C. to about 180° C. with a pressure of about 2 MPa to about 3 MPa.

Therefore, the conductive particles 12 may penetrate the support layer 132 and electrically connect the first pad electrode 26 and the output-side wire electrode 33 while contacting the two electrodes 26 and 33. The adhesive layer 11 may be firmly bonded to the first pad portion 25 and the second pad portion 32 as the material of the adhesive layer 11 penetrating the support layer 132 fills between the output-side wire electrodes 33.

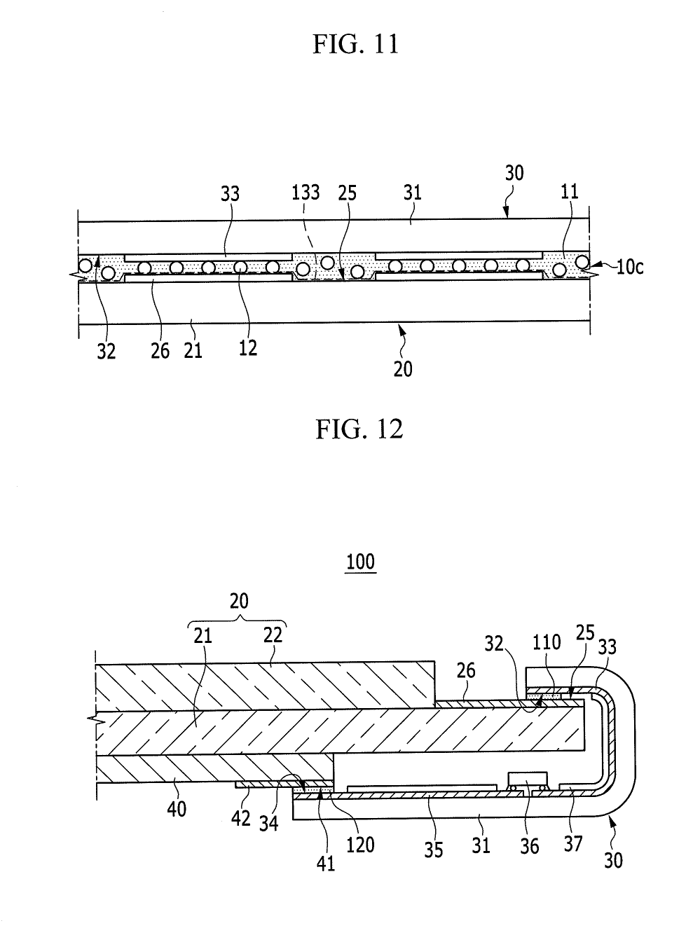

FIG. 11 illustrates a cross-sectional view of another example embodiment of the fourth operation shown in FIG. 6.

Referring to FIG. 11, when a display includes the anisotropic conductive film 10c of the third example embodiment, the support 133 may be melted and diffused during the thermo-compression process of the fourth operation. Therefore, conductive particles 12 may connect the first pad electrode 26 and the output-side wire electrode 33 while contacting the two electrodes 26, 33, and a material of the adhesive layer 11 may be filled between the first pad electrodes 26 and between the output-side wire electrodes 33 so that the first pad portion 25 and the second pad portion 32 may be firmly bonded to each other.

According to the manufacturing method of the display device, a pre-compression process may be omitted, and therefore the entire bonding process may be simplified and a failure in adherence due to pre-curing of the adhesive may be reduced or prevented. Further, a time period during which an anisotropic conductive film is exposed to an external environment after a releasing sheet is removed may be reduced, which may help prevent a connection failure due to inflow of foreign particles.

The above-described method for connecting the display panel 20 and the chip on film 30 using the anisotropic conductive films 10, 10b, and 10c may also be applied to connect, e.g., the chip on film 30 and a printed circuit board.

FIG. 12 illustrates a partial cross-sectional view of a display device according to an example embodiment.

Referring to FIG. 12, a display device 100 according to the present example embodiment includes a display panel 20, a printed circuit board 40 where a control circuit transmitting a control signal to the display panel 29 is disposed, and the chip on film 30 connecting the display panel 20 and the printed circuit board 40. The chip on film 30 may be replaced with, e.g., a tape carrier package or a flexible circuit board.

The display device 100 may include a first anisotropic conductive film 110 disposed between a first pad portion 24 and the chip on film 30 of the display panel 20, and may include a second anisotropic conductive film 120 disposed between a third pad portion 34 of the chip on film 30 and a fourth pad portion 41 of the printed circuit board 40. In the example embodiment shown in FIG. 12, the first anisotropic conductive film 110 and the second anisotropic conductive film 120 are in a state that a thermo-compression process is completed.

The display panel 20 may include a first substrate 21 and a second substrate 22, and the first pad portion 25 where first pad electrodes 26 are disposed may be provided in an edge of the first substrate 21, not being exposed to the second substrate 22. The display panel 20 may be, e.g., an organic light emitting diode (OLED) display including an organic light emitting diode, or a liquid crystal display (LCD) panel including a liquid crystal layer and a color filter layer.

The chip on film 30 may include a base film 31, wire patterns 33 and 35 formed in one side of the base film 31, a semiconductor chip 36 electrically connected with the wire patterns 33 and 35, and a solder resist 37 partially covering the wire patterns 33 and 35. The wire patterns 33 and 35 may include an output-side wire electrode 33 and an input-side wire electrode 35 that are disposed in the opposite side, with the semiconductor chip 36 interposed therebetween.

The second pad portion 32 to which the output-side wire electrodes 33 are exposed may be disposed at one edge of the chip on film 30, and the third pad portion 34 to which the input-side wire electrodes 35 are exposed may be disposed at an opposite edge of the chip on film 30. The second pad electrodes may be are disposed in the fourth pad portion 41 of the printed circuit board 40. The chip on film 30 may be bendable. Thus, the chip on film 30 may be bent to make the printed circuit board 40 disposed in a rear side of the display panel 20.

The first anisotropic conductive film 110 may be formed according to an embodiment, e.g., any one of the anisotropic conductive films 10, 10b, and 10c respectively shown in FIG. 9, FIG. 10, and FIG. 11. In the present example embodiment, the first anisotropic conductive film 110 connects the first pad electrodes 26 of the first pad portion 25 and the output-side wire electrodes 33 of the second pad portion 32, and bonds the two electrodes 26 and 33 to each other.

In the example embodiment shown in FIG. 9, the adhesive layer 11, the conductive particles 12, and the mesh-shaped support layer 13 are disposed between the first pad portion 25 and the second pad portion 32. In the example embodiment shown in FIG. 10, the adhesive layer 11, the conductive particles 12, and the support layer 132 (ruptured due to pressure) are disposed between the first pad portion 25 and the second pad portion 32. In the example embodiment shown in FIG. 11, the adhesive layer 11 and the conductive particles 12 are disposed between the first pad portion 25 and the second pad portion 32.

The second anisotropic conductive film 120 may be formed according to an embodiment, e.g., any one of the anisotropic conductive films 10, 10b, and 10c respectively shown in FIG. 9, FIG. 10, and FIG. 11. In the present example embodiment, the second anisotropic conductive film 110 connects the input-side wire electrodes 35 of the third pad portion 34 and the second pad electrodes 42 of the fourth pad portion 41, and bonds the two electrodes 35 and 42 to each other.

In the example embodiment shown in FIG. 9, the adhesive layer 11, the conductive particles 12, and the mesh-shaped support layer 13 are disposed between the third pad portion 34 and the fourth pad portion 41. In the example embodiment shown in FIG. 10, the adhesive layer 11, the conductive particles 12, and the support layer 132 (ruptured due to pressure) are disposed between the third pad portion 34 and the fourth pad portion 41. In the example embodiment shown in FIG. 11, the adhesive layer 11 and the conductive particles 12 are disposed between the third pad portion 34 and the fourth pad portion 41.

By way of summation and review, an anisotropic conductive film (ACF) may be formed as a film-shaped adhering member having conductive particles dispersed into an adhesive. The anisotropic conductive film may be formed of an adhesive layer in which the conductive particles are dispersed and a releasing sheet disposed at one side of the adhesive layer, and may be used to connect a display panel and a chip on film, and connect the chip on film and a printed circuit board (PCB) in the display device.

A general bonding process for connecting a display panel and a chip on film may include a pre-compression process in addition to a main compression process. In the pre-compression process, the anisotropic conductive film may be temporarily attached to a pad portion of the display panel using low heat and pressure. After that, the releasing sheet may be removed and the display panel may be transferred to a next process. In the main compression process, the anisotropic conductive film may be completely attached using high heat and pressure while the chip on film is disposed thereon. Such a bonding process includes two compression processes. Thus, the entire process may become complicated, and the adhesive may be undesirably cured in advance by heat during the pre-compression process, which may cause deterioration of adherence of the anisotropic conductive film. Further, the pre-compressed anisotropic conductive film may be exposed to an external environment until being covered with the chip on film, and therefore the connection may be deteriorated due to inflow of foreign materials.

As described above, embodiments relate to an anisotropic conductive film that may simplify a bonding process, a display device having the same, and a manufacturing method of the display device. Embodiments may provide an anisotropic conductive film that may simplify a bonding process and prevent an adhesion failure resulting from pre-curing of an adhesive and a connection failure due to flow of foreign materials, a display device having the anisotropic conductive film, and a manufacturing method of the display device. A pre-compression process may be omitted. Thus, the entire bonding process may be simplified and a bonding failure due to pre-curing of an adhesive may be reduced or prevented. In addition, a time that the anisotropic conductive film is exposed to the external environment with the releasing sheet removed may be minimized. Thus, a connection failure due to inflow of foreign materials may be reduced or prevented.

<Description of symbols>

| 10, 10a, 10b, 10c: anisotropic conductive film | |
|---|---|
| 11: adhesive layer | 12: conductive particles |
| 13, 132, 133: support layer | 14: releasing sheet |
| 20: display panel | 25: first pad portion |
| 30: chip on film | 32: second pad portion |
| 34: third pad portion | 40: printed circuit board |
| 41: fourth pad portion | |

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An anisotropic conductive film, comprising:
an adhesive layer formed of a polymer resin;
conductive particles dispersed in the adhesive layer;
a support layer disposed at one side of the adhesive layer and maintaining the adhesive layer in a film shape; and
a releasing sheet disposed at one side of the support layer.

2. The anisotropic conductive film as claimed in claim 1, wherein the support layer is formed in the shape of a mesh having a plurality of openings.

3. The anisotropic conductive film as claimed in claim 2, wherein a diameter of each of the plurality of openings is greater than a diameter of the conductive particles.

4. The anisotropic conductive film as claimed in claim 2, wherein the openings have a size that is about 10 to about 20 times greater than a diameter of the conductive particles.

5. The anisotropic conductive film as claimed in claim 2, wherein a heat resisting temperature of the support layer is higher than a thermal curing temperature of the polymer resin.

6. The anisotropic conductive film as claimed in claim 5, wherein the support layer includes one or more of polyphenylene sulfide, polyetheretherketone, polyphthalamide, thermoplastic polyimide, polysulfone, polyethersulfone, or polyetherimide.

7. The anisotropic conductive film as claimed in claim 1, wherein the support layer is formed of an insulation layer having a rupture pressure of about 2 MPa to about 3 MPa.

8. The anisotropic conductive film as claimed in claim 1, wherein the support layer is formed of an insulation layer having a melting temperature that is lower than a thermal curing temperature of the polymer resin.

9. The anisotropic conductive film as claimed in claim 1, wherein the adhesive layer includes:
a first layer in which the conductive particles are disposed in the polymer resin; and
a second layer formed of only the polymer resin.

10. A method of manufacturing a display device, the method comprising:
preparing an adhesive layer, conductive particles being dispersed into the adhesive layer, a support layer being disposed at one side of the adhesive layer and maintaining the adhesive layer in a film shape, and a releasing sheet being disposed at one side of the support layer;
removing the releasing sheet;
disposing the adhesive layer and the support layer on a first pad portion of a display panel; and
disposing a second pad portion of a chip on film on the adhesive layer and the support layer, and connecting and bonding the first pad portion and the second pad portion to each other by thermally compressing the support layer.

11. The method as claimed in claim 10, wherein the support layer is formed in the shape of a mesh having a plurality of openings, and a heat resisting temperature of the support layer is higher than a thermal curing temperature of the adhesive layer.

12. The method as claimed in claim 11, wherein a material of the adhesive layer fills the plurality of openings during the thermo-compression process, and the conductive particles are disposed between electrodes of the first pad portion and electrodes of the second pad portion in the plurality of openings.

13. The method as claimed in claim 10, wherein the support layer has a rupture pressure of about 2 MPa to about 3 MPa, and the support layer is ruptured during the thermo-compression process such that the material of the adhesive layer and the conductive particles penetrate the support layer.

14. The method as claimed in claim 10, wherein the support layer has a melting temperature that is lower than a thermal curing temperature of the adhesive layer, and melted and then diffused during the thermo-compressing process.

15. A display device, comprising:
a display panel provided with a first pad portion;
a chip on film provided with a second pad portion that faces the first pad portion; and
a first anisotropic conductive film disposed between the first pad portion and the second pad portion, the first anisotropic conductive film connecting and bonding the first pad portion and the second pad portion to each other, the first anisotropic conductive film including:
an adhesive layer formed of a polymer resin,
conductive particles connecting the first pad portion and the second pad portion, and
a support layer disposed at one side of the adhesive layer.

16. The display device as claimed in claim 15, wherein the support layer is formed in the shape of a mesh forming a plurality of openings filled with the polymer resin.

17. The display device as claimed in claim 15, wherein the support layer forms a plurality of rupture openings, and the polymer resin and the conductive particles penetrate the support layer in the plurality of rupture openings.

18. The display device as claimed in claim 15, wherein:
the chip on film is provided with a third pad portion,
the display device further comprises:
a printed circuit board provided with a fourth pad portion facing the third pad portion; and
a second anisotropic conductive film disposed between the third pad portion and the fourth pad portion to connect and bond the third pad portion and the fourth pad portion to each other, and
the second anisotropic conductive film includes:
an adhesive layer formed of a polymer resin,
conductive particles connecting the third pad portion and the fourth pad portion, and
a support layer disposed at one side of the adhesive layer.

19. The display device as claimed in claim 18, wherein the support layer of the second anisotropic conductive film is formed in the shape of a mesh forming a plurality of openings filled with the polymer resin.

20. The display device as claimed in claim 18, wherein the support layer of the second anisotropic conductive film forms a plurality of rupture openings, and the polymer resin and the conductive particles of the second anisotropic conductive film penetrate the support layer of the second anisotropic conductive film in the plurality of rupture openings.
